(19) United States
(12) Patent Application Publication
(10) Pub. No.: US 2025/0212473 A1
(43) Pub. Date: Jun. 26, 2025

(54) NITRIDE SEMICONDUCTOR DEVICE AND METHOD OF MANUFACTURING THE SAME

(71) Applicant: FUJI ELECTRIC CO., LTD., Kawasaki-shi (JP)

(72) Inventors: Ryo TANAKA, Hino-city (JP); Shinya TAKASHIMA, Hachioji-city (JP); Jun UZUHASHI, Tsukubashi (JP); Tadakatsu OHKUBO, Tsukubashi (JP)

(73) Assignee: FUJI ELECTRIC CO., LTD., Kawasaki-shi (JP)

(21) Appl. No.: 18/982,144

(22) Filed: Dec. 16, 2024

(30) Foreign Application Priority Data
Dec. 26, 2023 (JP) 2023-219433

(51) Int. Cl. H10D 62/13; H01L 21/265; H01L 21/266; H10D 30/01; H10D 30/66; H10D 62/00; H10D 62/10; H10D 62/85

(52) U.S. Cl. CPC H10D 62/153; H01L 21/26546; H01L 21/266; H10D 30/0291; H10D 30/665; H10D 62/01; H10D 62/107; H10D 62/8503

(57) ABSTRACT

Provided is a nitride semiconductor device including a p-type region having a high effective acceptor concentration while exhibiting good electrical characteristics, and a method of manufacturing the same. The nitride semiconductor device includes: a nitride semiconductor; and a p-type region provided in the nitride semiconductor. The p-type region includes an acceptor element and entirely has a concentration in a range of 5×10¹⁸ cm⁻³ or higher and 1×10²¹ cm⁻³ or lower. The p-type region includes a segregation part in which the acceptor element is partly segregated, and a matrix in which the acceptor element is not segregated. The concentration of the acceptor element in the segregation part is 4.6 times or smaller as high as that in the matrix.

### CROSS-REFERENCE TO RELATED APPLICATION

This application claims benefit of priority under 35 USC 119 based on Japanese Patent Application No. 2023-219433 filed on Dec. 26, 2023, the entire contents of which are incorporated by reference herein.

### BACKGROUND OF THE INVENTION

### 1. Field of the Invention

The present disclosure relates to nitride semiconductor devices and methods of manufacturing the same.

### 2. Description of the Related Art

Nitride semiconductor devices are known that have a vertical metal oxide semiconductor (MOS) structure, as disclosed in JP2019-096744A, for example.

Such a nitride semiconductor device uses magnesium (Mg) as a dopant so as to control a p-type conductivity, as disclose in JP2014-086698A, for example.

The use of Mg heavily doped and subjected to annealing at a high temperature could cause high-density segregation or deep diffusion of Mg, leading to a decrease in the concentration of Mg accordingly, as disclosed in Kumar et. Al., Appl. Phys. 126 (2019) 235704, and H. Sakurai et al., Appl. Phys. Lett. 115, 142104 (2019).

Demand for nitride semiconductor devices has been increased that include a p-type region having a high effective acceptor concentration while exhibiting good electrical characteristics.

### SUMMARY OF THE INVENTION

In view of the foregoing problems, the present disclosure provides a nitride semiconductor device including a p-type region capable of exhibiting good electrical characteristics, and a method of manufacturing the same.

To solve the problems described above, a nitride semiconductor device according to an aspect of the present disclosure includes a nitride semiconductor, and a p-type region provided in the nitride semiconductor. The p-type region includes an acceptor element and entirely has a concentration in a range of 5×10¹⁸ cm⁻³ or higher and 1×10²¹ cm⁻³ or lower. The p-type region includes a segregation part in which the acceptor element is partly segregated, and a matrix in which the acceptor element is not segregated. The concentration of the acceptor element in the segregation part is 4.6 times or smaller as high as that in the matrix.

A method of manufacturing a nitride semiconductor device according to the aspect of the present disclosure includes implanting impurity ions of an acceptor element from a front surface side of a nitride semiconductor into a predetermined region of the nitride semiconductor, implanting impurity ions of nitride from the front surface side into the predetermined region before or after the implanting the acceptor element, and forming a p-type region in the predetermined region of the nitride semiconductor by subjecting, to annealing, the nitride semiconductor to which the acceptor element and the nitride are implanted. The p-type region includes a segregation part in which the acceptor element is partly segregated, and a matrix in which the acceptor element is not segregated. The implanting the acceptor element is executed such that the entire predetermined region has a concentration of the acceptor element in a range of 5×10¹⁸ cm⁻³ or higher and 1×10² cm⁻³ or lower. The forming the p-type region sets a condition for the annealing so that the concentration of the acceptor element in the segregation part is 4.6 times or smaller as high as that in the matrix.

### BRIEF DESCRIPTION OF THE DRAWINGS

FIG. 1 is a plan view illustrating an example of a configuration of a GaN semiconductor device according to Embodiment 1 of the present disclosure;

FIG. 2 is a cross-sectional view illustrating the example of the configuration of the GaN semiconductor device according to Embodiment 1 of the present disclosure;

FIG. 3 is an enlarged cross-sectional view illustrating a repeated-unit structure of a vertical MOSFET according to Embodiment 1 of the present disclosure;

FIG. 4A is a cross-sectional view sequentially illustrating a method of manufacturing the vertical MOSFET according to Embodiment 1 of the present disclosure;

FIG. 4B is a cross-sectional view sequentially illustrating the method of manufacturing the vertical MOSFET according to Embodiment 1 of the present disclosure;

FIG. 4C is a cross-sectional view sequentially illustrating the method of manufacturing the vertical MOSFET according to Embodiment 1 of the present disclosure;

FIG. 4D is a cross-sectional view sequentially illustrating the method of manufacturing the vertical MOSFET according to Embodiment 1 of the present disclosure;

FIG. 4E is a cross-sectional view sequentially illustrating the method of manufacturing the vertical MOSFET according to Embodiment 1 of the present disclosure;

FIG. 4F is a cross-sectional view sequentially illustrating the method of manufacturing the vertical MOSFET according to Embodiment 1 of the present disclosure;

FIG. 5 is a cross-sectional view illustrating an example of a configuration of an evaluation device used for a conductivity-characteristic evaluation obtained by TLM according to an example of the present disclosure;

FIG. 6 is a graph showing experimental results of the conductivity-characteristic evaluation in a p-type region by TLM according to the present disclosure;

FIG. 7 is a graph showing experimental results of the conductivity-characteristic evaluation in the p-type region by TLM according to the present disclosure;

FIG. 8 is a graph showing experimental results of the conductivity-characteristic evaluation in the p-type region by TLM according to the present disclosure;

FIG. 9 is a graph showing experimental results of the conductivity-characteristic evaluation in the p-type region by TLM according to the present disclosure;

FIG. 10 is a 3-DAP diagram showing an example of analysis results of Mg segregation in the p-type region of a GaN substrate according to the example of the present disclosure;

FIG. 11 is a graph showing a relation between a Mg segregation ratio and a sheet resistance in the p-type region according to the example of the present disclosure;

FIG. 12 is a graph showing a relation between the Mg segregation ratio and a contact resistance in the p-type region according to the example of the present disclosure;

FIG. 13 is a graph showing a relation between the Mg segregation ratio and “the sheet resistance× a matrix Mg concentration” in the p-type region according to the example of the present disclosure;

FIG. 14 is a graph showing a relation between the Mg segregation ratio and “1/[the sheet resistance× the matrix Mg concentration]” in the p-type region according to the example of the present disclosure;

FIG. 15 is a cross-sectional view illustrating an example of a configuration of a vertical MOSFET according to Embodiment 2 of the present disclosure;

FIG. 16 is a cross-sectional view illustrating an example of a configuration of a vertical MOSFET according to Embodiment 3 of the present disclosure;

FIG. 17 is a cross-sectional view illustrating an example of a configuration of an edge termination area in a GaN semiconductor device according to Embodiment 4 of the present disclosure; and

FIG. 18 is a cross-sectional view illustrating another example of the configuration of the edge termination area in the GaN semiconductor device according to Embodiment 4 of the present disclosure.

### DETAILED DESCRIPTION

Some embodiments according to the present disclosure are descried below.

In the following explanations regarding the drawings, the same or similar components are denoted by the same or similar reference numerals. The drawings are illustrated schematically, and relationships between thicknesses and planar dimensions, and proportions of the thicknesses of the respective members are not drawn to scale. The specific thicknesses and dimensions therefore should be determined in accordance with the explanations below. It should also be understood that the relationships or proportions of the dimensions between the drawings can differ from each other.

The following explanations define the respective directions by an X-axis direction, a Y-axis direction, and a Z-axis direction for some cases. For example, the X-axis direction and the Y-axis direction are each a direction parallel to a front surface 10a of a GaN substrate 10 described below. The X-axis direction and the Y-axis direction are each also referred to as a horizontal direction. The Z-axis direction is a direction orthogonal to the front surface 10a of the GaN substrate 10. The X-axis direction, the Y-axis direction, and the Z-axis are perpendicular to each other.

In the following explanations, the positive direction in the Z-axis may be referred to as an “upper side”, and the negative direction in the Z-axis may be referred to as a “lower side”. The definitions of the “upper side” and the “lower side” do not necessarily mean the directions vertical to the ground. In other words, the respective directions of the “upper side” and the “lower side” are not limited to the gravity direction. The definitions regarding the “upper side” and the “lower side” are used only for illustration purposes to define the relative positional relationship among regions, layers, films, and a substrate, which do not limit the technical idea of the present disclosure. For example, when the observing direction of the sheet is changed by 180 degrees, the definitions of the “upper side” and the “lower side” shall be reversed.

The signs “+” and “−” added to the signs “p” and “n” indicating the conductivities signify that a semiconductor region with such a sign added has either a higher impurity concentration or a lower impurity concentration than other semiconductor regions without the sign “+” or “−” added. It should be understood that the respective semiconductor regions to which the same sign “p” (or the same sign “n”) is added do not necessarily or strictly have the same impurity concentration.

### Embodiment 1

### <Configuration Example of Gallium Nitride Semiconductor Device>

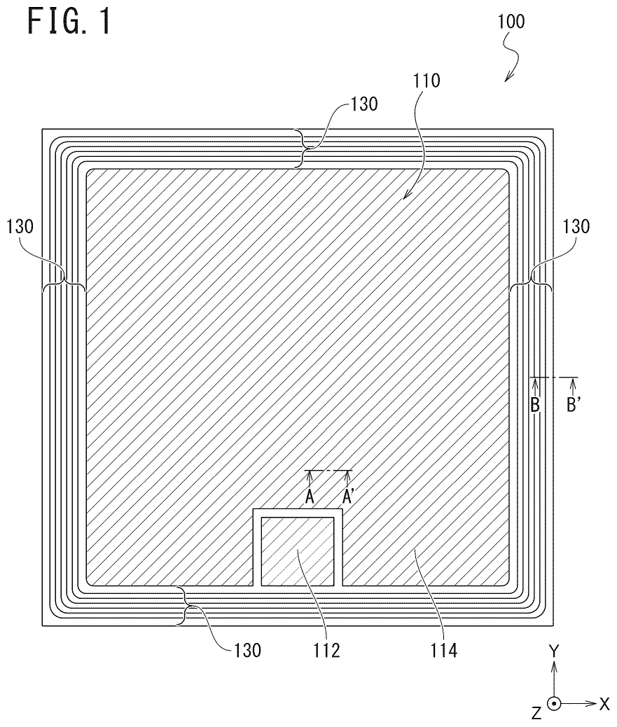

FIG. 1 is a plan view illustrating an example of a configuration of a gallium nitride semiconductor device 100, which is an example of a nitride semiconductor device and is also referred to below as a “GaN semiconductor device”, according to Embodiment 1 of the present disclosure. FIG. 1 is the X-Y plan view. As illustrated in FIG. 1, the GaN semiconductor device 100 includes an active area 110 and an edge termination area 130. The active area 110 includes a gate pad 112 and a source pad 114. The gate pad 112 and the source pad 114 are electrode pads electrically connected to a gate electrode 44 and a source electrode 54 respectively as described below.

The edge termination area 130 surrounds the circumference of the active area 110 in the planar view in the Z-axis direction. The edge termination area 130 may have any one or more of a guard ring structure, a field plate structure, and a junction termination extension (JTE) structure. The edge termination area 130 can have a function of preventing an electric-field concentration in the active area 110 such that a depletion layer caused in the active area 110 is led to expand toward the edge termination area 130.

### <Configuration Example of Vertical MOSFET>

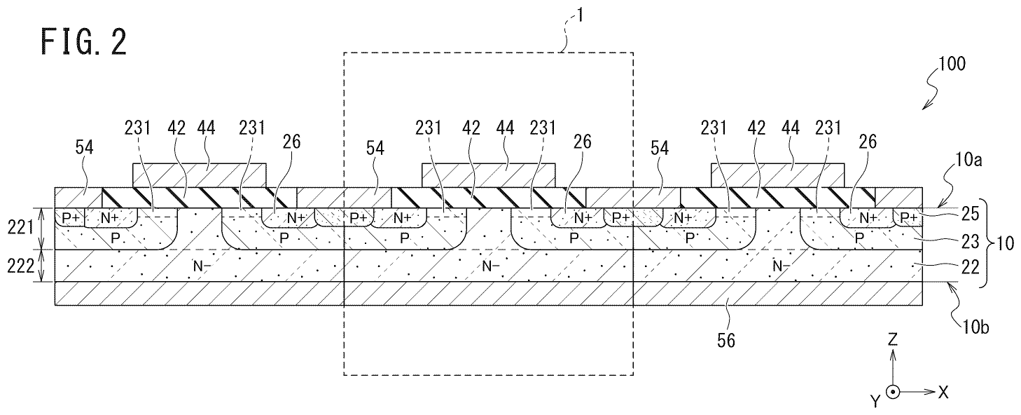

FIG. 2 is a cross-sectional view illustrating an example of a configuration of the GaN semiconductor device 100 according to Embodiment 1 of the present disclosure. FIG. 2 illustrates the cross section of the active area 110 taken along line A-A′in FIG. 1. FIG. 2 omits the illustration of the gate pad 112 and the source pad 114 illustrated in FIG. 1. The GaN semiconductor device 100 includes a plurality of vertical metal-oxide-semiconductor field-effect transistors (MOSFETs) 1 illustrated in FIG. 2. The GaN semiconductor device 100 includes the plural vertical MOSFETs 1 arranged repeatedly in the Y-axis direction.

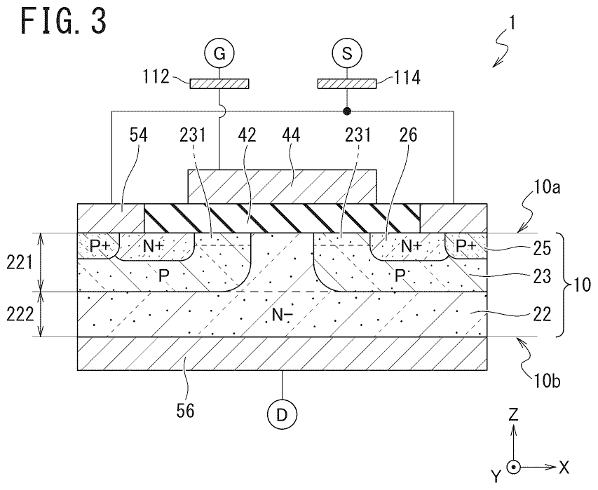

FIG. 3 is an enlarged cross-sectional view illustrating a repeated-unit structure of the respective vertical MOSFETs 1 according to Embodiment 1 of the present disclosure. As illustrated in FIG. 3, the vertical MOSFET 1 includes a gallium nitride substrate 10, which is an example of a “nitride semiconductor” according to the present disclosure and is referred to below as a GaN substrate, a gate insulating film 42, a gate electrode 44 provided on the gate insulating film 42, a source electrode 54, which is an example of an “electrode” according to the present disclosure, and a drain electrode 56.

The GaN substrate (the nitride semiconductor) 10 is a GaN single-crystal substrate. The GaN substrate 10 is an n⁻-type substrate, for example. The GaN substrate 10 has a front surface 10a and a rear surface 10b located opposite to the front surface 10a. The GaN substrate 10 may be a low-dislocation free-standing GaN substrate having a threading dislocation density of less than 1×10⁷ cm⁻², for example.

A donor (n-type impurities) included in the GaN substrate 10 may be any one or more of silicon (Si), germanium (Ge), and oxygen (O). An acceptor element (p-type impurities) included in the GaN substrate 10 may be any one or more of magnesium (Mg), calcium (Ca), beryllium (Be), and zinc (Zn).

The use of the GaN substrate 10 serving as a low-dislocation free-standing GaN substrate can decrease a leakage of current in a power device having a large area when formed in the GaN substrate 10. This can contribute to manufacturing power devices at a high yield rate. In addition, the use of such a GaN substrate can avoid a deep diffusion of the implanted impurity ions along the dislocation during annealing executed in a procedure of manufacturing the vertical MOSFETs 1.

The GaN substrate 10 may include a GaN single-crystal substrate and a GaN layer having a single crystal epitaxially grown on the GaN single-crystal substrate. In such a case, the GaN single-crystal substrate may be either of n⁺-type or n-type, and the GaN layer may be either of n-type or n⁻-type.

The vertical MOSFET 1 includes semiconductor material that is GaN. In this case, the semiconductor material may include either one or both of aluminum (Al) and indium (In). The semiconductor material may be a mixed-crystal semiconductor having a slight amount of Al and In, which is AlxInyGal-x-yN (0≤x<1, 0≤y<1). The present disclosure illustrates the case of including GaN in which AlxInyGal-x-yN fulfills x=y=0.

The GaN substrate 10 includes a drift region 22, a well region 23, which is an example of a “p-type well region” according to the present disclosure, a contact region 25, which is an example of a “p-type region” according to the present disclosure, and a source region 26, which is an example of a “n-type source region” according to the present disclosure. The well region 23, the contact region 25, and the source region 26 are each obtained such that impurity ions are implanted into a predetermined depth from the front surface 10a of the GaN substrate 10 and are then activated by annealing.

The contact region 25 is provided on the front surface side of the well region 23, for example. The well region 23 is a p-type region, and the contact region 25 is a p⁺-type region. The well region 23 has a concentration of the acceptor element (a p-type impurity concentration) lower than that of the contact region 25. The well region 23 and the contact region 25 each include at least either Mg or Be as the acceptor element (the p-type impurities).

For example, the well region 23 and the contact region 25 include Mg as the acceptor element. The concentration of Mg included in the well region 23 is in a range of 1×10¹⁶ cm⁻³ or higher and 3×10¹⁸ cm⁻³ or lower. The concentration of Mg included in the entire contact region 25 (also referred to below as an “entire Mg concentration”) is in a range of 5×10¹⁸ cm⁻³ or higher and 1×10²¹ cm⁻³ or lower, and more preferably in a range of 1×10¹⁹ cm⁻³ or higher and 2×10²⁰ cm⁻³ or lower. The concentration of Mg in the contact region 25 at a depth of 30 nanometers from the front surface 10a of the GaN substrate 10, which is a position adjacent to the front surface at which the concentration of Mg can be measured at high accuracy, is 2×10¹⁹ cm⁻³, for example.

A Mg peak position at which the concentration of Mg is maximum in the contact region 25 corresponds to a position of 50 nanometer or shallower in the depth direction (the Z-axis direction) from the front surface 10a of the GaN substrate 10, for example. The range of the contact region 25 in the depth direction (the Z-axis direction) is 80 nanometers or shallower from the front surface 10a of the GaN substrate 10, for example.

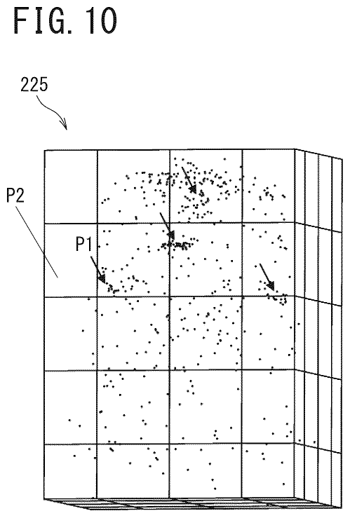

As described below with reference to FIG. 10, the contact region 25 has a segregation part (also referred to below as a “Mg segregation part”) in which the acceptor element such as Mg is partly segregated, and a matrix in which Mg is not segregated. The concentration of Mg in the matrix (also referred to below as a “matrix Mg concentration”) is in a range of 5×10¹⁸ cm⁻³ or higher and 2×10²⁰ cm⁻³ or lower, and more preferably in a range of 5×10¹⁸ cm⁻³ or higher and 4×10¹⁹ cm⁻³ or lower, for example. The concentration of Mg in the matrix in which Mg is not segregated at a depth of 30 nanometers from the front surface 10a of the GaN substrate 10 is 7×10¹⁸ cm⁻³ or less, for example.

The concentration of Mg in the Mg segregation part (also referred to below as a “segregation Mg concentration”) is 0.4 times or greater and 4.6 times or smaller as high as that in the matrix, and more preferably 0.4 times or greater and 3 times or smaller.

The contact region 25 has a sheet resistance of 1.8×10⁵ Ω/sq or smaller, for example. As described below, the contact region 25 is in contact with (connected to) the source electrode 54. A contact resistance between the contact region 25 and the source electrode 54, which is a contact resistance at a current density of 1 A/cm², is 0.2 Ωcm² or smaller.

The drift region 22 is an n⁻-type region, and the source region 26 is an n⁺-type region. The source region 26 has a concentration of the donor element (an n-type impurity concentration) lower than that of the drift region 22. The drift region 22 and the source region 26 include Si as n-type impurities, for example. The n-type impurity concentration of the drift region 22 is the same as that of the GaN substrate 10. In this case, the n-type impurity ions are not necessarily implanted into the drift region 22. The source region 26 is provided on the front surface side of the well region 23. The source region 26 is formed such that the impurity ions of Si are implanted into the front surface side of the well region 23 and are then activated by annealing.

As illustrated in FIG. 3, the upper part of the source region 26 is exposed on the front surface 10a of the GaN substrate 10. The source region 26 has a bottom part and a first side part that are in contact with the well region 23, and a second side part that is in contact with the contact region 25. The first side part of the source region 26 is located toward a region 231 (referred to below as a channel region) of the vertical MOSFET 1 in which a channel is formed. The second side part of the source region 26 is located opposite to the first side part in the X-axis direction.

The upper part of the contact region 25 is exposed on the front surface 10a of the GaN substrate 10. The contact region 25 has a side part that is in contact with the source region 26, and a bottom part that is in contact with the well region 23. The thickness of the contact region 25, which is a depth from the front surface 10a of the GaN substrate 10 to the bottom surface of the contact region 25, is 80 nanometers or smaller, for example.

Each of the well region 23, the contact region 25, and the source region 26 in the planar view in the Z-axis direction may have any shape determined as appropriate, and can have a straight shape extending in the X-axis direction, for example. In such a case, the well region 23, the contact region 25, and the source region 26 each have a stripe shape extending in the X-axis direction.

An upper part 221 of the drift region 22 (referred to below as an “upper region”) is exposed on the front surface 10a of the GaN substrate 10. The upper region 221 is in contact with the gate insulating film 42 on the front surface 10a. The upper region 221 is located between the paired parts of the well region 23 opposed to each other in the Y-axis direction. The upper region 221 can be referred to as a JFET region.

A lower part 222 of the drift region 22 (referred to below as a “lower region”) is in contact with the bottom of the well region 23. The lower region 222 is located between the upper region 221 and the drain electrode 56 and between the well region 23 and the drain electrode 56. The lower region 222 may be provided continuously in the Y-axis direction between the plural vertical MOSFETs 1 (the plural unit structures) repeatedly arranged in the Y-axis direction.

The drift region 22 serves as a current path between the drain electrode 56 and the channel region 231. The contact region 25 has a function of reducing a contact resistance between the source electrode 54 and the well region 23. The contact region 25 also serves as a hole-extraction path upon gate-off.

The gate insulating film 42 is a silicon oxide film (a SiO₂ film), for example. The gate insulating film 42 is provided on the flat front surface 10a, for example.

The gate electrode 44 is arranged over the channel region 231 with the gate insulating film 42 interposed. The gate electrode 44 is a planar-type electrode provided on the flat gate insulating film 42. The gate electrode 44 includes material different from that of the gate pad 112. The gate electrode 44 includes polysilicon doped with impurity ions, while the gate pad 112 includes Al or an Al—Si alloy.

The source electrode 54 is provided on the front surface 10a of the GaN substrate 10. The source electrode 54 is in contact with a part of the source region 26 and the contact region 25. The source electrode 54 may be further provided on the gate electrode 44 with an interlayer insulating film (not illustrated) interposed. The interlayer insulating film may cover the respective upper and side parts of the gate electrode 44 so as not to lead the gate electrode 44 to be electrically connected to the source electrode 54.

The source electrode 54 includes the same material as the source pad 114. For example, the source electrode 54 including Al or an Al—Si alloy also serves as the source pad 114. The source electrode 54 may be provided with a barrier metal layer between the front surface 10a of the GaN substrate 10 and Al (or Al—Si). The barrier metal layer may include titanium (Ti). The drain electrode 56 is provided on the rear surface 10b side of the GaN substrate 10 so as to be in contact with each other. The drain electrode 56 includes the material similar to that included in the source electrode 54.

FIG. 3 indicates the gate terminal, the source terminal, and the drain terminal respectively by G, S, and D. When a potential of a threshold voltage or greater is applied to the gate electrode 44 through the gate terminal G, for example, an inversion layer is formed in the channel region 231. When a predetermined high potential is applied to the drain electrode 56 and a low potential (such as a ground potential) is applied to the source electrode 54 in the state in which the inversion layer is formed in the channel region 231, a current flows from the drain terminal D toward the source terminal S. When a potential lower than the threshold voltage is applied to the gate electrode 44, no inversion layer is formed in the channel region 231, and the current is then blocked. This configuration thus can allow the switching of the current between the source terminal S and the drain terminal D in the vertical MOSFET 1.

### <Method of Manufacturing Vertical MOSFET>

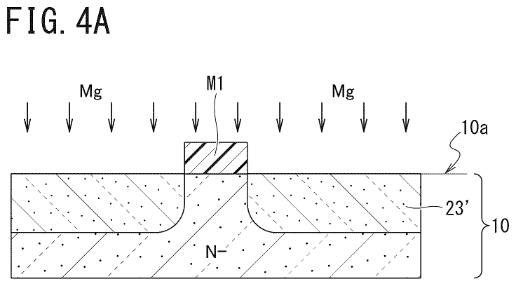

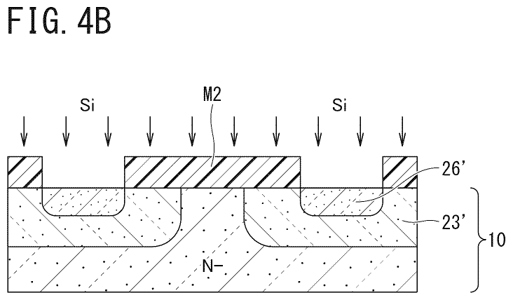

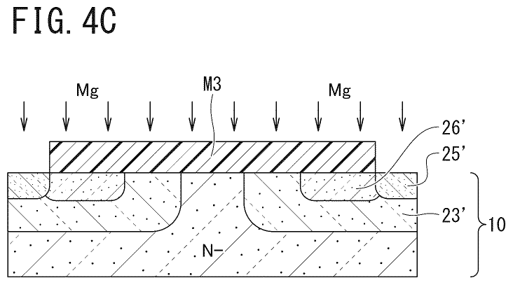

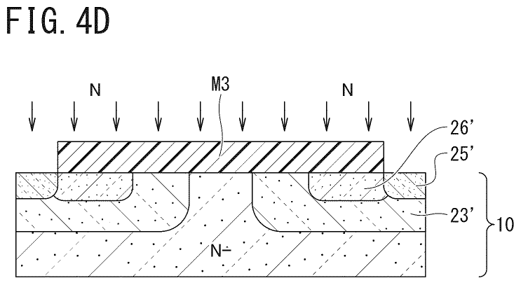

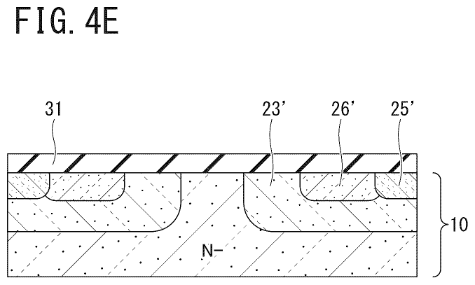

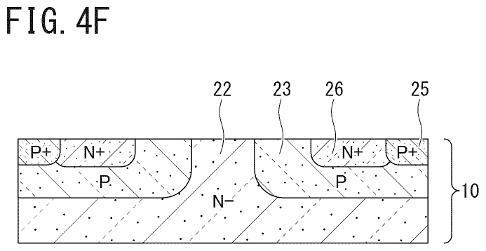

A method of manufacturing the vertical MOSFET 1 according to Embodiment 1 of the present disclosure is described below. FIG. 4A to FIG. 4F are cross-sectional views sequentially illustrating the method of manufacturing the vertical MOSFET 1 according to Embodiment 1 of the present disclosure. The vertical MOSFET 1 is manufactured by use of various kinds of apparatuses, such as a film-deposition apparatus, an exposing apparatus, and an etching apparatus. These apparatuses are collectively referred to below as a manufacturing apparatus.

As illustrated in FIG. 4A, the manufacturing apparatus implants impurity ions of Mg as an acceptor element to a predetermined region (referred to below as a “well-formation region”) 23′ in which the well region 23 (refer to FIG. 3) is to be formed in the GaN substrate 10. For example, the manufacturing apparatus forms a mask M1 on the front surface 10a of the GaN substrate 10. The mask M1 is a SiO₂ film or a photoresist that can be selectively removed from the GaN substrate 10. In the active area 110 (refer to FIG. 1), the mask M1 has a shape so as to open the well-formation region 23′ on the upper side while covering the upper parts of the other regions. The manufacturing apparatus implants the impurity ions of Mg to the GaN substrate 10 provided with the mask M1. The manufacturing apparatus then removes the mask M1 from the upper side of the GaN substrate 10 after the ion implantation.

The step of implanting the impurity ions of Mg illustrated in FIG. 4A sets an implantation energy (an accelerating voltage) and a dose of Mg such that the concentration of Mg adjacent to the front surface 10a of the GaN substrate 10 is in a range of 1×10¹⁶ cm⁻³ or higher and 3×10¹⁸ cm⁻³ or lower. The expression “adjacent to the front surface” as used herein refers to a depth up to 50 nanometers from the front surface 10a, for example.

Alternatively, the step of implanting the impurity ions of Mg illustrated in FIG. 4A may set the implantation energy and the dose of Mg such that the concentration of Mg not only adjacent to the front surface 10a of the GaN substrate 10 but also in the entire well-formation region 23′ is in a range of 1×10¹⁶ cm³ or higher and 3×10¹⁸ cm⁻³ or lower. The step of implanting the impurity ions of Mg may be either a single-step ion implantation in which the accelerating energy has a single condition or a multiple-step ion implantation in which the accelerating energy has plural conditions.

Next, as illustrated in FIG. 4B, the manufacturing apparatus implants n-type impurity ions of Si to a predetermined region (referred to below as a “source-formation region”) 26′ in which the source region is to be formed in the GaN substrate 10. For example, the manufacturing apparatus forms a mask M2 on the GaN substrate 10. The mask M2 is a SiO₂ film or a photoresist. In the active area 110, the mask M2 has a shape so as to open the source-formation region 26′ on the upper side while covering the upper parts of the other regions. The manufacturing apparatus implants the impurity ions of Si to the GaN substrate 10 provided with the mask M2. The manufacturing apparatus then removes the mask M2 from the upper side of the GaN substrate 10 after the ion implantation.

Next, as illustrated in FIG. 4C, the manufacturing apparatus implants p-type impurity ions of Mg to a predetermined region (referred to below as a “contact-formation region”, which is an example of a “predetermined region” according to the present disclosure) 25′ in which the contact region is to be formed in the GaN substrate 10. For example, the manufacturing apparatus forms a mask M3 on the GaN substrate 10. The mask M3 is a SiO₂ film or a photoresist. In the active area 110 (refer to FIG. 1), the mask M3 has a shape so as to open the contact-formation region 25′ on the upper side while covering the upper parts of the other regions. The manufacturing apparatus implants the impurity ions of Mg to the GaN substrate 10 provided with the mask M3.

The step of implanting the impurity ions of Mg illustrated in FIG. 4C sets the implantation energy (the accelerating voltage) at either a single stage or multiple stages such that the implanted depth from the front surface 10a of the GaN substrate 10 to an implantation-peak position is 50 nanometers or shallower and such that the implanted range from the front surface 10a of the GaN substrate 10 is 80 nanometers or smaller, for example. This step also sets the dose of Mg (the acceptor element) such that the concentration of the implanted Mg at the implantation-peak position is in a range of 5×10¹⁸ cm⁻³ or higher and 1×10²¹ cm⁻³ or lower, and for example, set to 1×10¹⁹ cm⁻³.

Next, as illustrated in FIG. 4D, the manufacturing apparatus implants impurity ions of nitrogen (N) to the contact-formation region 25′ in the GaN substrate 10. For example, the manufacturing apparatus implants the impurity ions of N to the GaN substrate 10 provided with the mask M3. The manufacturing apparatus then removes the mask M3 from the upper side of the GaN substrate 10 after the ion implantation.

The step of implanting the impurity ions of N illustrated in FIG. 4D sets the implantation energy (the accelerating voltage) such that the implanted depth from the front surface 10a of the GaN substrate 10 to the implantation-peak position is 50 nanometers or shallower, for example. This step may execute the ion implantation of N at the same implantation energy as in the ion implantation of Mg illustrated in FIG. 4C. This step also sets the dose of N such that the concentration of the implanted N at the implantation-peak position is 0.1 times or greater and 10 times or smaller, and for example, one time as high as the concentration of Mg at the implantation-peak position of Mg.

The step illustrated in FIG. 4D may implant the impurity ions of N not only to the contact-formation region 25′ but also to the well-formation region 23′.

The manufacturing method according to Embodiment 1 of the present disclosure may exchange the execution orders between the step of implanting Mg illustrated in FIG. 4C and the step of implanting N illustrated in FIG. 4D. Namely, the step of implanting Mg illustrated in FIG. 4C may be executed after the step of implanting N illustrated in FIG. 4D.

Next, as illustrated in FIG. 4E, the manufacturing apparatus forms an insulating passivation film 31 on the front surface 10a of the GaN substrate 10. The passivation film 31 has a function of preventing nitrogen atoms from being released from the GaN substrate 10 during annealing. The GaN substrate 10, if the nitrogen atoms are released, is provided with nitrogen voids at the released positions. The nitrogen voids if formed could serve as donor defects and thus impede the expression of the p-type characteristics. To deal with such a problem, the manufacturing apparatus thus provides the passivation film 31 on the GaN substrate 10.

The passivation film 31 preferably has the properties of exhibiting high heat resistance, contributing to high adhesion to the GaN substrate 10, avoiding diffusion of impurity ions toward the GaN substrate 10, and facilitating a selective removal from the GaN substrate 10. The passivation film 31 is an aluminum nitride (AlN) film, a SiO₂ film, or a silicon nitride (SiN) film. The passivation film 31 may be either a single film or a stacked film including two or more of the AlN film, the SiO₂ film, and the SiN film. An insulating film serving as a base of the passivation film 31 may be provided between the GaN substrate 10 and the passivation film 31. The insulating film serving as a base of the passivation film 31 can be a SiO₂ film, for example.

Next, the manufacturing apparatus subjects the GaN substrate 10 covered with the passivation film 31 to annealing at a maximum temperature in a range of 1200° C. or higher and 2000° C. or lower, and more preferably at a maximum temperature in a range of 1300° C. or higher and 2000° C. or lower. The annealing is rapid thermal processing, for example. The execution of the annealing activates Mg and Si implanted to the GaN substrate 10. This step forms the p-type well region 23, the p⁺-type contact region 25, and the n⁺-type source region 26 and also defines the drift region 22 in the GaN substrate 10, as illustrated in FIG. 4F. This annealing can also recover defects in the GaN substrate 10 to some extent caused by the ion implantation. The manufacturing apparatus then removes the passivation film 31 from the upper side of the GaN substrate 10 after the annealing.

Next, the manufacturing apparatus forms the gate insulating film 42 (refer to FIG. 3) on the front surface 10a of the GaN substrate 10. Next, the manufacturing apparatus forms the gate electrode 44 (refer to FIG. 3) and the source electrode 54 (refer to FIG. 3). Next, the manufacturing apparatus forms the interlayer insulating film (not illustrated) on the gate electrode 44. Next, the manufacturing apparatus forms the gate pad 112 (refer to FIG. 1) electrically connected to the gate electrode 44 and the source pad 114 (refer to FIG. 1) electrically connected to the source electrode 54. The manufacturing apparatus also forms the drain electrode 56 on the rear surface 10b of the GaN substrate 10 before or after these steps. The vertical MOSFET 1 illustrated in FIG. 3 is thus completed.

<Differences from Configuration Obtained by Epitaxial Growth>

The embodiment of the present disclosure forms the p-type contact region 25 by the ion implantation of Mg and the subsequent ion implantation of N, or alternatively, by the ion implantation of N and the subsequent ion implantation of Mg. The formation of the contact region 25 by the ion implantation provides the configuration that can differ from that obtained by epitaxial growth in the following features A to C:

A. The contact region 25 has the same impurity concentrations of elements other than Mg as the other circumferential regions, such as the p-type well region 23 and the n⁺-type source region 26. For example, the contact region 25 and the well region 23 have the same impurity concentrations of the elements other than Mg, and the contact region 25 and the source region 26 have the same impurity concentrations of the elements other than Mg and Si. If the contact region with the same configuration as the contact region 25 is formed by the epitaxial growth, the difference in the impurity concentrations of the elements other than Mg (or other than both Mg and Si) is caused between the contact region and the other regions. The embodiment of the present disclosure does not cause such a problem.

B. The contact region 25 doss not have a peak of Si at the interfaces between the contact region 25 and the other circumferential regions, such as the p-type well region 23 and the n⁺-type source region 26. If the contact region with the same configuration as the contact region 25 is formed by the epitaxial growth, a peak of Si is caused at the interfaces between the contact region and the other circumferential regions. The peak of Si is caused such that Si present in an atmosphere in a chamber is introduced to the respective interfaces during re-growth. The embodiment of the present disclosure does not cause such a problem.

C. There are no (or almost no) steps between the surface of the contact region 25 and the surfaces of the other circumferential regions, such as the p-type well region 23 and the n⁺-type source region 26. If the contact region with the same configuration as the contact region 25 is formed by the epitaxial growth, any steps between the surface of the contact region and the surfaces of the other circumferential regions would be provided because of etching or selective epitaxial growth. The embodiment of the present disclosure does not cause such a problem.

### EXAMPLES

Next, experiments for evaluation executed by the present inventors and results thus obtained are described below as examples of the present disclosure.

### I. Conductivity-Characteristic Evaluation by TLM

The present inventors examined a relation between the implanted-ion amount of Mg and N illustrated in FIG. 4C and FIG. 4D and the electrical characteristics of the p-type region (for example, the contact region 25) obtained by the ion implantation of Mg and N. This examination was executed through conductivity-characteristic evaluation by TLM.

I. i. Evaluation Device

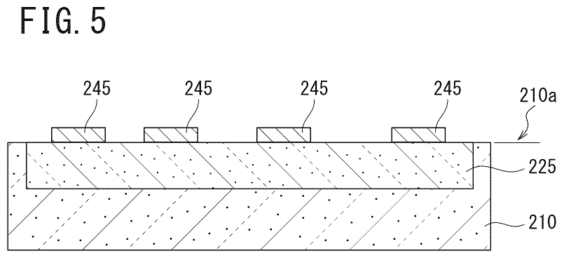

FIG. 5 is a cross-sectional view illustrating a configuration example of an evaluation device 200 used for the conductivity-characteristic evaluation by TLM according to an example of the present disclosure. As illustrated in FIG. 5, the evaluation device was obtained such that impurity ions of Mg and N were selectively implanted to a front surface 210a side of a GaN substrate 210, and the GaN substrate 210 implanted with Mg and N was then subjected to annealing to activate Mg so as to form a p-type region 225, and a plurality of electrodes 245 were further formed on the p-type region 225.

The GaN substrate 210 used in the example is the same as the GaN substrate 10 illustrated in FIG. 1. The conditions for implanting Mg and N and the conditions for the annealing are the same as those of the conditions for forming the contact region 25 as described with reference to FIG. 4C to FIG. 4F. The experiments for evaluation use Mg and N with the same dose, namely, a ratio of the implanted amount of Mg to the implanted amount of N is 1:1. The respective electrodes 245 formed in the example include the same material (such as Al) as the source electrode 54 illustrated in FIG. 1.

The respective electrodes 245 illustrated in FIG. 5 were formed to include the common material and have the common size. The gaps between the respective electrodes 245 next to each other in the lateral direction in FIG. 5 (in the X-axis direction, for example) were set to be increased gradually from the right to the left. As described below, a plurality of evaluation devices 200 were prepared with the dose of Mg and N changed.

I. ii. Correlation between Implanted Amount of Mg and N and Electrical Characteristics

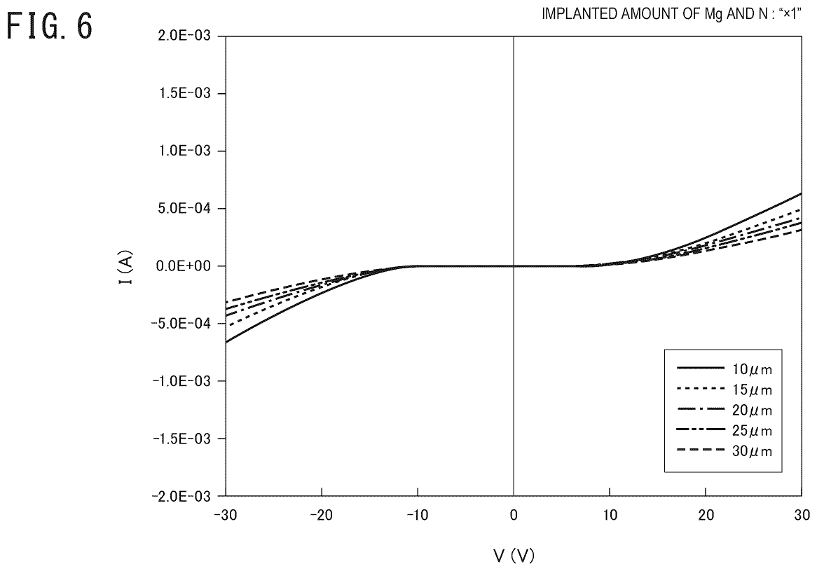

FIG. 6 to FIG. 9 are graphs showing experimental results of the conductivity-characteristic evaluation for the p-type region 225 by TLM. FIG. 6 to FIG. 9 each show a voltage V (V) on the axis of abscissas and a current I (A) on the axis of ordinates. FIG. 6 to FIG. 9 each indicate 10 μm, 15 μm, 20 μm, 25 μm, and 30 μm that are the gaps between the respective electrodes 245 applied with voltage. The symbol “E” shown on the axis of ordinates in FIG. 6 to FIG. 9 refers to a power of ten. The symbol “E” has the same meaning in the following explanations regarding the drawings and the tables described below.

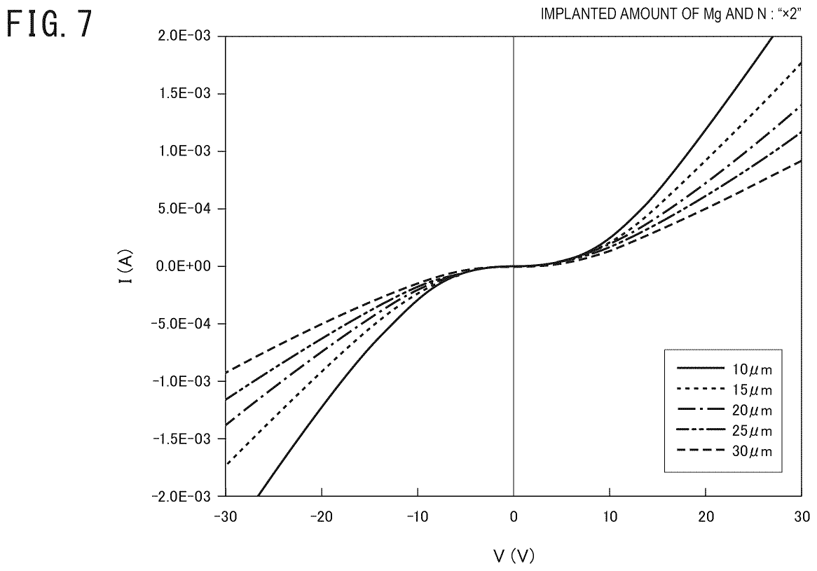

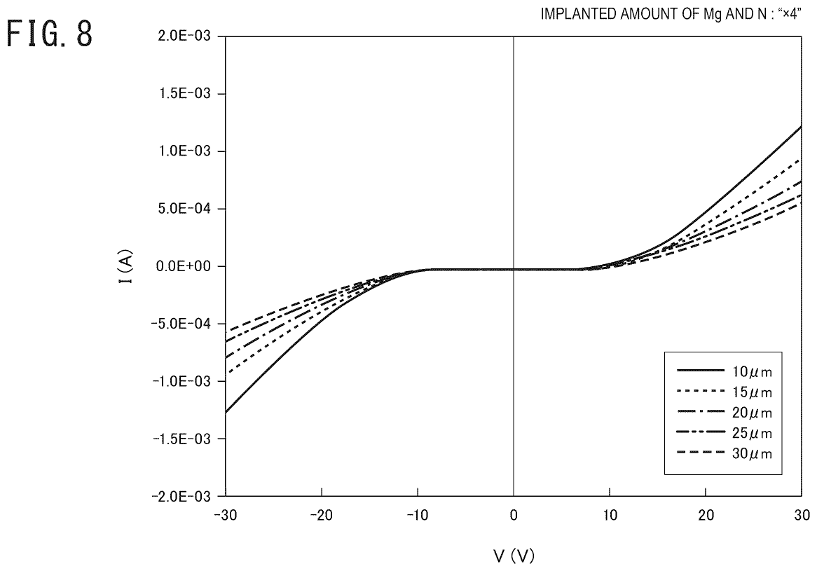

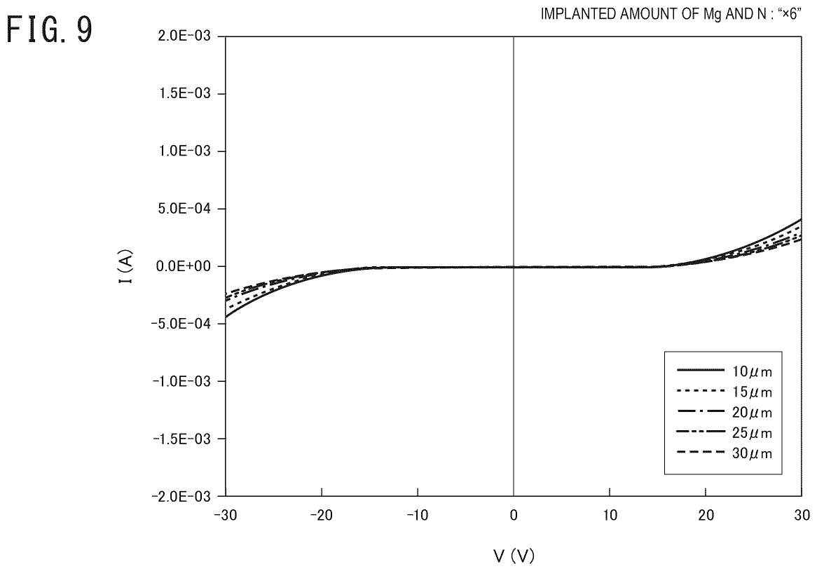

FIG. 6 to FIG. 9 differ from each other in the data regarding the implanted amount of Mg and N. In particular, when the implanted amount of Mg and N in FIG. 6 is defined as 1, FIG. 7 shows the data twice the implanted amount of Mg and N in FIG. 6, FIG. 8 shows the data four times the implanted amount of Mg and N in FIG. 6, and FIG. 9 shows the data six times the implanted amount of Mg and N in FIG. 6. The ratio of the implanted amount of Mg to the implanted amount of N is set to 1:1 in FIG. 6 to FIG. 9.

The implanted amount of Mg and N in FIG. 6 is hereinafter indicated by “×1”, the implanted amount of Mg and N in FIG. 7 is indicated by “×2”, the implanted amount of Mg and N in FIG. 8 is indicated by “×4”, and the implanted amount of Mg and N in FIG. 9 is indicated by “×6”.

Table 1 shows the data regarding a sheet resistance and a contact resistance in the p-type region 225 calculated according to the experimental results shown in FIG. 6 to FIG. 9. Table 1 shows the data regarding the contact resistance at a current density of 1 A/cm².

TABLE 1

| | IMPLANTED AMOUNT OF Mg AND N | | | |
|---|---|---|---|---|
| | ×1 | ×2 | ×4 | ×6 |
| SHEET RESISTANCE (Ω/sq) | 3.0E+5 | 1.5E+5 | 1.8E+5 | 2.7E+5 |
| CONTACT RESISTANCE | 0.20 | 0.076 | 0.20 | 0.37 |
| (Ωcm²) | | | | |

The evaluation revealed, as shown in FIG. 6 to FIG. 9 and Table 1, that the case in which the implanted amount was “×2” had the best results regarding the sheet resistance and the contact resistance, and also showed a high effective acceptor concentration (effective Na) when the impurity ions of Mg and N were implanted with the same dose and were then increased. The evaluation also revealed that an excessive increase of the dose of Mg and N deteriorated the characteristics.

II. Correlation between Implanted Amount of Mg and N and Mg Segregation

FIG. 10 is a three-dimension atom probe (3-DAP) microscope diagram illustrating analysis results of Mg segregation in the p-type region 225 of the GaN substrate according to the example of the present disclosure. The parts indicated by the arrows in FIG. 10 at which dots are gathered each correspond to the Mg segregation part at which Mg is segregated. For example, when the p-type region 225 is formed by the manufacturing method as described above with reference to FIG. 4C to FIG. 4F, the Mg segregation parts P1 at which Mg is partly segregated and the matrix P2 at which no Mg is segregated are caused in the p-type region 225, as illustrated in FIG. 10.

The concentration of Mg in the matrix P2 (the matrix Mg concentration) can be measured by 3-DAP. The entire concentration of Mg in the p-type region 225 including the Mg segregation parts P1 and the matrix P2 can be measured by secondary ion mass spectrometry (SIMS).

The present inventors measured the entire concentration of Mg by SIMS and the matrix Mg concentration by 3DAP in the p-type region 225 of the evaluation device 200 illustrated in FIG. 5. The present inventors also calculated the concentration of Mg in the segregation parts (the segregation Mg concentration) in accordance with a difference between the entire concentration of Mg and the matrix Mg concentration. The present inventors further calculated a Mg segregation ratio, which is a ratio of the segregation Mg concentration to the matrix Mg concentration. The measurement results by SIMS and 3DAP and the data regarding the segregation Mg concentration and the Mg segregation ratio calculated in accordance with the measurement results are shown in FIG. 6 to FIG. 9, for example. The measurements were executed under the respective conditions in which the implanted amount of Mg and N in the case of each of “×1”, “×2”, “×4”, and “×6”. Table 2 shows the results of the measurements and the calculations thus obtained.

TABLE 2

| | IMPLANTED AMOUNT OF Mg AND N | | | |
|---|---|---|---|---|
| | ×1 | ×2 | ×4 | ×6 |
| ENTIRE Mg CONCENTRATION (cm⁻³) | 7E+18 | 2E+19 | 5E+19 | 9E+19 |
| MATRIX Mg CONCENTRATION | 5E+18 | 7E+18 | 9E+18 | 1.5E+19 |
| (cm⁻³) | | | | |
| SEGREGATION Mg CONCENTRATION | 2E+18 | 1.3E+19 | 4.1E+19 | 7.5E+19 |
| (cm⁻³) | | | | |
| SEGREGATION Mg CONCENTRATION/ | 0.4 | 1.9 | 4.6 | 5 |
| MATRIX Mg CONCENTRATION | | | | |

The measurements revealed, as shown in Table 2, that the increase of the implanted amount of Mg and N (Mg:N=1:1) leads to the increase in the matrix Mg concentration, but at the same time, also leads to the increase in the segregation of Mg. The matrix Mg concentration would be decreased by the corresponding increased amount of the segregation of Mg. The segregation Mg concentration is thus required to be decreased to a predetermined level or lower with respect to the matrix Mg concentration. Namely, the Mg segregation ratio, which is the ratio of the segregation Mg concentration to the matrix Mg concentration, is required to be decreased to a predetermined level or lower.

III. Correlation between Mg Segregation Ratio and Electrical Characteristics

As shown in Table 1, the contact resistance in the case in which the implanted amount of Mg and N is “×4” is the same as that in the case of “×1”, while the contact resistance in the case in which the implanted amount of Mg and N is “×6” is higher than that in the case of “×1”. The results revealed that the upper limit of the implanted amount of Mg and N is “×4” in order to have the preferable values for the sheet resistance and the contact resistance.

Further, as shown in Table 2, the Mg segregation ratio (the ratio of the segregation Mg concentration to the matrix Mg concentration) in the case in which the implanted amount of Mg and N is “×4” is 4.6. The results revealed that decreasing the Mg segregation ratio to 4.6 or smaller is effective in order to improve the electrical characteristics (such as the sheet resistance and the contact resistance) in the p-type region.

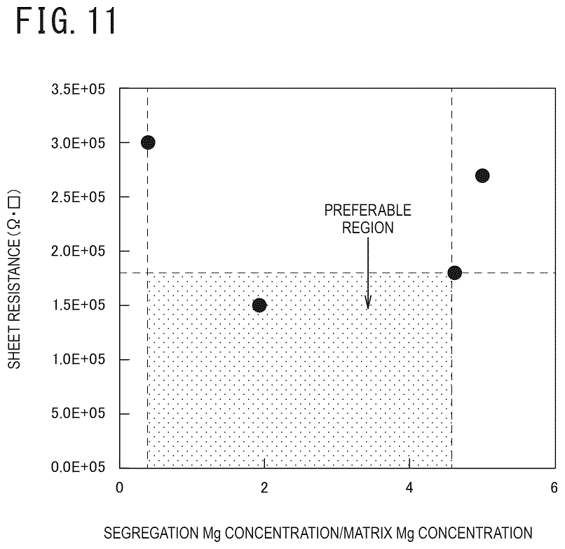

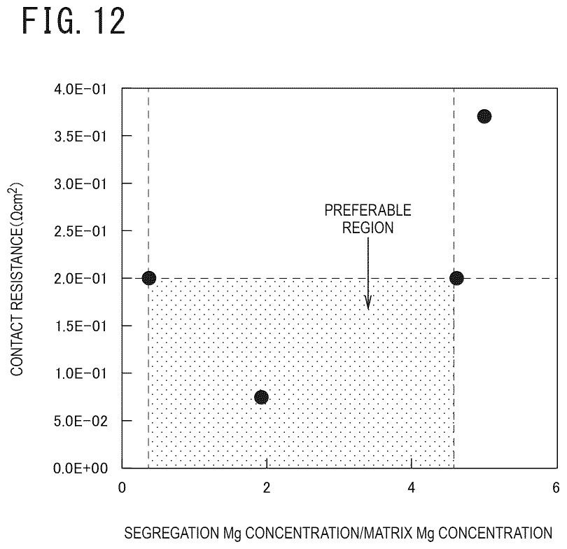

FIG. 11 is a graph showing a relation between the Mg segregation ratio and the sheet resistance in the p-type region according to the example of the present disclosure. FIG. 11 shows the Mg segregation ratio on the axis of abscissas and the sheet resistance (Ω/sq) on the axis of ordinates. FIG. 12 is a graph showing a relation between the Mg segregation ratio and the contact resistance in the p-type region according to the example of the present disclosure. FIG. 12 shows the Mg segregation ratio on the axis of abscissas and the contact resistance (Ωcm²) on the axis of ordinates. The respective graphs shown in FIG. 11 and FIG. 12 are derived from the data shown in Tables 1 and 2.

The shaded regions in the respective graphs in FIG. 11 and FIG. 12 are each a preferable range for the electrical characteristics in the p-type region. The upper limit on the axis of abscissas defining the preferable range is the Mg segregation ratio of 4.6 in the case in which the implanted amount of Mg and N is “×4” (refer to Table 2), and the lower limit on the axis of abscissas is the Mg segregation ratio of 0.4 in the case in which the implanted amount of Mg and N is “×1” (refer to Table 2). The value on the axis of abscissas (the Mg segregation ratio), when the p-type region is formed not by the ion implantation but by the epitaxial growth, is zero.

The upper limit on the axis of ordinates defining the preferable range in the respective graphs in FIG. 11 and FIG. 12 is the sheet resistance and the contact resistance in the case in which the implanted amount of Mg and N is “×4” (refer to Table 1). In particular, the upper limit of the sheet resistance on the axis of ordinates in FIG. 11 is 1.8E+5 (Ω/sq), and the upper limit of the contact resistance on the axis of ordinates in FIG. 12 is 2.0E−1 (Ωcm²), namely, 0.20 (Ωcm²).

As described above, decreasing the Mg segregation ratio to 4.6 or smaller is effective in order to improve the electrical characteristics (such as the sheet resistance and the contact resistance) in the p-type region. Such a decrease can increase the effective acceptor concentration (the effective Na) in the p-type region. To further improve the electrical characteristics, maximizing the matrix Mg concentration is effective while decreasing the Mg segregation ratio to 4.6 or smaller. For example, increasing the matrix Mg concentration to 5E+18 cm³ (corresponding to the value in the case of “×1” in Table 2) or higher while decreasing the Mg segregation ratio to 4.6 or smaller can further enhance the effective Na in the p-type region.

III. i. Supplementary Explanation

The sheet resistance is inversely proportional to the effective acceptor concentration (the effective Na). If the sheet resistance is high even the Mg concentration is high, a compensating acceptor concentration (a factor that would counteract the acceptor, such as defects and unintended impurities) could be high, causing fluctuations in the characteristics accordingly. In view of this, the sheet resistance in the p-type region is preferably 1.8E+5 (Ω/sq) or lower, as shown in FIG. 11.

In addition, the contact resistance has an influence on hole extraction. The contact resistance in the p-type region is thus preferably 0.20 (Ωcm²) or lower, as shown in FIG. 12.

### IX. Introduction of New Indicator

The relation between the Mg segregation concentration and the sheet resistance described above is as shown in the graph in FIG. 11. If some samples having different Mg concentrations, such as the respective samples indicated by “×1”, “×2”, “×4”, and “×6” shown in Tables 1 and 2, are compared, the use of the sheet resistance would not be sufficient as an indicator to indicate the difference between the samples.

For example, the value of the sheet resistance fluctuates depending on an activated rate of Mg, in addition to the Mg concentration. The activated rate of Mg also fluctuates depending on the amount of Mg entering sites other than the acceptor sites, such as parts between the GaN lattices, or depending on the amount of the compensating acceptor derived from residual defects. The sheet resistance thus would not strictly reflect the difference in the activation between the respective samples if the ratio of Mg entering the sites other than the acceptor sites to the dose of Mg or the activated rate of Mg significantly differs between the respective samples.

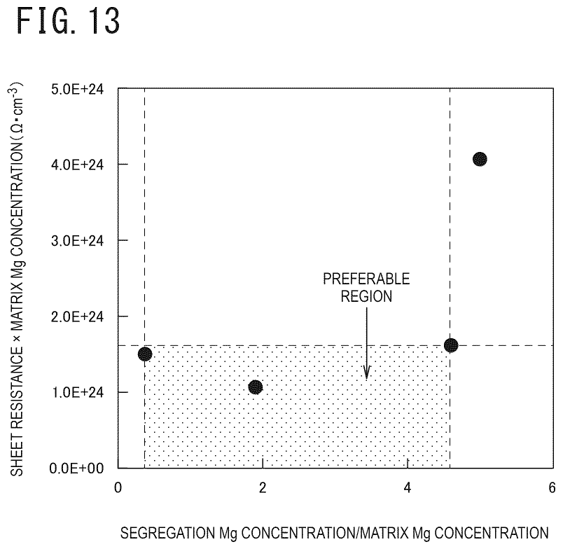

To deal with such a problem, the present inventors found out a new indicator, “the sheet resistance× the matrix Mg concentration”, that can reflect the difference of the activated state between the respective samples in numerical values. FIG. 13 is a graph in which the data shown in the graph in FIG. 11 is re-plotted by the new indicator, “the sheet resistance× the matrix Mg concentration”.

FIG. 13 is a graph showing a relation between the Mg segregation ratio and “the sheet resistance× the matrix Mg concentration” in the p-type region according to the example of the present disclosure. FIG. 13 shows the Mg segregation ratio on the axis of abscissas and “the sheet resistance× the matrix Mg concentration” on the axis of ordinates. The shaded region in the graph in FIG. 13 is a preferable range for the electrical characteristics in the p-type region. The upper limit on the axis of abscissas defining the preferable range is the Mg segregation ratio of 4.6 in the case in which the implanted amount of Mg and N is “×4” (refer to Table 2), and the lower limit on the axis of abscissas is the Mg segregation ratio of 0.4 in the case in which the implanted amount of Mg and N is “×1” (refer to Table 2).

The upper limit on the axis of ordinates defining the preferable range in the graph in FIG. 13 is “the sheet resistance× the matrix Mg concentration” in the case in which the implanted amount of Mg and N is “×4” (refer to Table 1), which is 1.6E+24 Ω/(sq·cm³).

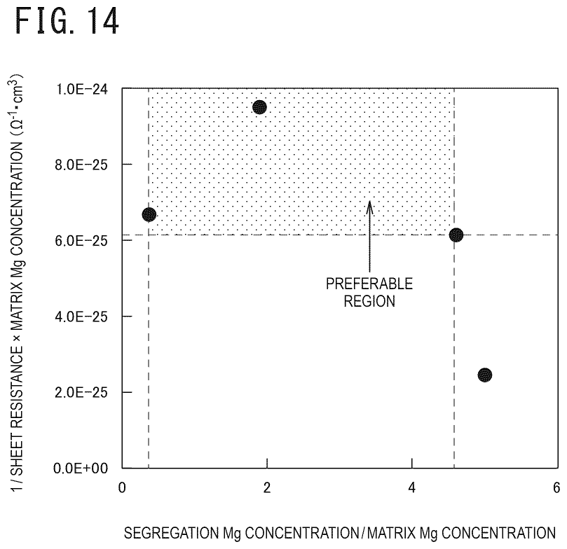

FIG. 14 is a graph showing a relation between the Mg segregation ratio and “1/[the sheet resistance× the matrix Mg concentration]” in the p-type region according to the example of the present disclosure. The graph in FIG. 14 shows the data in which the axis of ordinates in FIG. 13 is transformed into a reciprocal inverse. The new indicator, “the sheet resistance× the matrix Mg concentration”, is described in detail below.

The sheet resistance in the p-type region is given by the following formula A:

Sheet resistance=1/[charge×carrier concentration×mobility×thickness] A

The carrier concentration is not strictly but approximately proportional to “the impurity concentration× the activated rate”.

On the assumption that the mobility, the thickness, and the charge in the p-type region are not changed regardless of the conditions, the sheet resistance is given by the following respective formulae B and C:

$$Sheet resistance ∝ 1 / [ impurity concentration \times activated rate ] \times 1 / [ charge \times mobility \times thickness ] \qquad B$$

$$Activated rate ∝ 1 / [ sheet resistance \times impurity concentration ] \qquad C$$

In this example, the impurity ions that can serve as an acceptor are Mg in the matrix. The impurity concentration in the formula C is thus equal to the matrix Mg concentration.

$$Activated rate ∝ 1 / [ sheet resistance \times matrix Mg concentration ] \qquad C ’$$

As given by the formula C′, the sheet resistance× the matrix Mg concentration is substantially inversely proportional to the activated rate of Mg. The sheet resistance×the matrix Mg concentration indirectly shows the activated rate of Mg. The activated rate of Mg can be higher as the value of the sheet resistance× the matrix Mg concentration is smaller, and the activated rate of Mg can be lower as the value of the sheet resistance× the matrix Mg concentration is larger.

The state in which the activated rate of Mg is low means that Mg enters the sites other than the acceptor sites, such as the parts between the GaN lattices, or that the amount of the compensating acceptor derived from residual defects is large. Such a state is presumed to have a problem with operational stability such as long-term contact reliability.

In the example of the present embodiment, the Mg segregation ratio (=the segregation Mg concentration/the matrix Mg concentration) in the p-type region is preferably in the range of 0.4 or greater and 4.6 or smaller, and the value of the sheet resistance× the matrix Mg concentration is preferably 1.6E+24 Ω/(sq·cm³) or smaller, as shown in FIG. 13. According to this example, the use of the new indicator, “the sheet resistance× the matrix Mg concentration”, can reflect the difference of the activated state between the respective samples in the numerical values of the indicator. Defining the p-type region by use of the new indicator thus can provide the contact region 25 with the higher effective Na and the greater electrical characteristics.

### Effects of Embodiment 1

As described above, the GaN semiconductor device 100 according to Embodiment 1 of the present disclosure includes the GaN substrate 10 and the p⁺-type contact region 25 provided in the GaN substrate 10. The concentration of Mg in the entire contact region 25 is in the range of 5×10¹⁸ cm⁻³ or higher and 1×10²¹ cm⁻³ or lower. The contact region 25 includes the Mg segregation part P1 in which Mg is partly segregated and the matrix P2 in which no Mg is segregated. The concentration of Mg in the Mg segregation part P1 is 4.6 times or smaller as high as that in the matrix P2.

This configuration can provide the contact region 25 with the higher effective acceptor concentration (effective Na) and the greater electrical characteristics, that is, the sheet resistance and the contact resistance are both small, for example. Maximizing the matrix Mg concentration (for example, increasing to 5E+18 cm⁻³ or higher) while decreasing the Mg segregation ratio to 4.6 or smaller can further improve the electrical characteristics.

Further, the product of the sheet resistance in the contact region 25 by the matrix Mg concentration in the contact region 25 preferably results in 1.6×10²⁴ Ω/(sq·cm³) or smaller. The present embodiment defines the preferable range for the electrical characteristics by the ratio of the segregation Mg concentration to the matrix Mg concentration, and further introduces the new indicator, “the sheet resistance× the matrix Mg concentration”, that can reflect the difference of the activated state between the respective samples in the numerical values. The value of this new indicator is set to 1.6×10²⁴ Ω/(sq·cm³) or smaller. This thus can provide the contact region 25 with the higher effective Na and the greater electrical characteristics.

A method of manufacturing the GaN semiconductor device 100 according to Embodiment 1 of the present disclosure includes a step of implanting the impurity ions of Mg to the predetermined region (such as the contact-formation region 25′) in the GaN substrate 10 from the front surface 10a side of the GaN substrate 10, a step of implanting the impurity ions of N to the contact-formation region 25′ from the front surface 10a side of the GaN substrate 10 before or after the step of implanting Mg, and a step of subjecting the GaN substrate 10 to which Mg and N are implanted to annealing so as to form the p⁺-type contact region 25 in the contact-formation region 25′ in the GaN substrate 10. The contact region 25 includes the Mg segregation part P1 in which Mg is partly segregated and the matrix P2 in which no Mg is segregated. The step of implanting the impurity ions of Mg sets the concentration of Mg in the entire contact-formation region 25′ in the range of 5×10¹⁸ cm⁻³ or higher and 1×10²¹ cm⁻³ or lower. The step of forming the contact region 25 sets the conditions for the annealing such that the concentration of Mg in the Mg segregation part P1 (the segregation Mg concentration) is 4.6 times or smaller as high as that in the matrix P2 (the matrix Mg concentration). This method thus can provide the contact region 25 with the higher effective Na and the greater electrical characteristics.

### Embodiment 2

The embodiment of the present disclosure may subject the drift region 22 to doping (counter doping) in order to increase a concentration of n-type impurities.

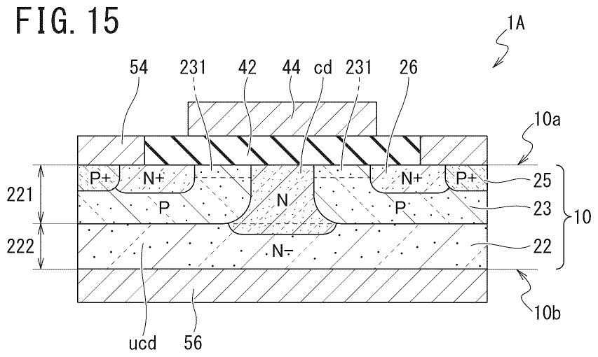

FIG. 15 is a cross-sectional view illustrating a vertical MOSFET 1A according to Embodiment 2 of the present disclosure. As illustrated in FIG. 15, the vertical MOSFET 1A according to Embodiment 2 includes a doped region cd of n-type provided in the n⁻-type drift region 22. The doped region cd is a region doped with n-type impurities such as Si. The region other than the doped region cd in the drift region 22 is a non-doped region ucd. The doped region cd has a higher concentration of the n-type impurities such as Si than the non-doped region ucd.

The doped region cd is located closer to the front surface 10a of the GaN substrate 10 than the non-doped region ucd. For example, the doped region cd is continuously provided along the entire upper region (the JFET region) 221 and the edge side of the lower region 222 in contact with the upper region 221.

The configuration according to this embodiment can also provide the contact region 25 with the higher effective Na and the greater electrical characteristics, that is, the sheet resistance and the contact resistance are both small, for example. Further, the configuration of the vertical MOSFET 1A can increase the concentration of the n-type impurities in the drift region 22 at a part adjacent to the channel region 231, so as to reduce an ON-resistance while avoiding a reduction in breakdown voltage.

### Embodiment 3

Embodiments 1 and 2 according to the present disclosure described above are illustrated with the case of including the vertical MOSFET in which the GaN semiconductor device 100 has a planar gate structure. The vertical MOSFET according to the present disclosure, however, is not limited to the planar gate structure, but may have a trench gate structure. For example, the GaN semiconductor device 100 may include a vertical MOSFET 1B having a trench gate structure described below.

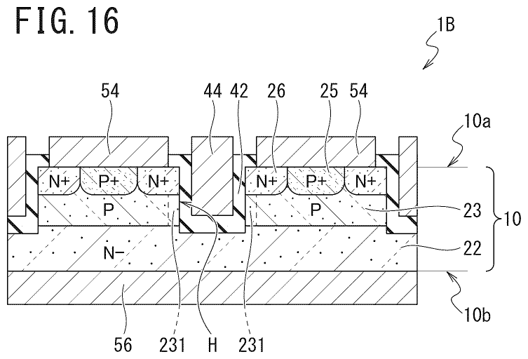

FIG. 16 is a cross-sectional view illustrating the vertical MOSFET 1B according to Embodiment 3 of the present disclosure. As illustrated in FIG. 16, the vertical MOSFET 1B according to Embodiment 3 has trenches H provided in the GaN substrate 10. The trenches H are open toward the front surface 10a side of the GaN substrate 10. The respective trenches H have a greater depth than the p-type well region 23 so that the respective bottoms of the trenches H reach the n⁻-type region.

The gate insulating film 42 and the gate electrode 44 are buried inside the respective trenches H. The bottom and side surfaces on the inner side of the respective trenches H are covered with the gate insulating film 42. The gate electrode 44 is buried in the respective trenches H with the gate insulating film 42 interposed. In the vertical MOSFET 1B, a region in the GaN substrate 10 opposed to the gate electrode 44 with the gate insulating film 42 on the inner side surface of the trench H interposed serves as a channel region 231.

The configuration according to this embodiment can also provide the contact region 25 with the higher effective Na and the greater electrical characteristic, that is, the sheet resistance and the contact resistance are both small, for example. Further, the vertical MOSFET 1B having the trench gate structure can include the channel region 231 with higher density. The vertical MOSFET 1B thus can enable a minimization in element size and an increase in channel density.

### Embodiment 4

Embodiments 1 to 3 according to the present disclosure described above illustrate the case of providing the p⁺-type contact region 25 around the front surface 10a of the GaN substrate 10, namely, at a shallow part from the front surface 10a. The application of the present disclosure is not limited to the provision of the contact region 25 arranged at a shallow part from the front surface 10a of the GaN substrate 10. The present disclosure may be applied to a case of providing a p-type region arranged at a deep part from the front surface 10a of the GaN substrate 10.

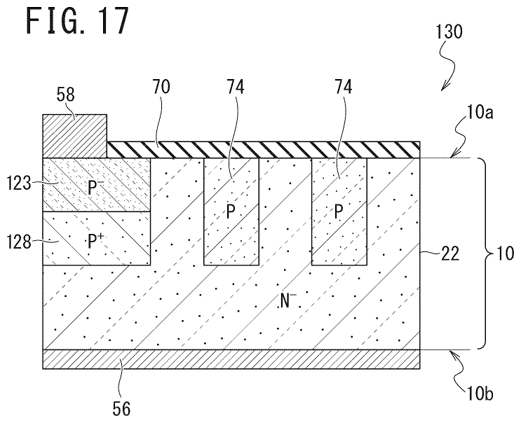

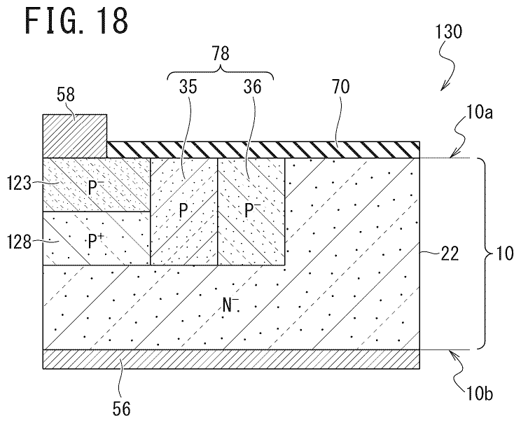

FIG. 17 and FIG. 18 are cross-sectional views each illustrating an example of a configuration of the edge termination area 130 of the GaN semiconductor device 100 according to Embodiment 4 of the present disclosure. FIG. 17 and FIG. 18 illustrate two examples of the cross section taken along line B-B′ in FIG. 1. In particular, FIG. 17 illustrates a case in which the edge termination area 130 has a guard ring structure 74, and FIG. 18 illustrates a case in which the edge termination area 130 has a junction termination extension (JTE) structure 78.

As illustrated in FIG. 17 and FIG. 18, the active area 110 and the edge termination area 130 are provided commonly with the GaN substrate 10 and the drain electrode 56. The structure inside the GaN substrate 10 in the edge termination area 130 differs from the structure inside the GaN substrate 10 in the active area 110, as illustrated in FIG. 17 and FIG. 18. The edge termination area 130 includes an electrode 58 provided on the front surface 10a of the GaN substrate 10, and a passivation film 70 provided on the front surface 10a of the GaN substrate 10.

The edge termination area 130 illustrated in FIG. 17 includes the drift region 22, a base region 123, the guard ring structure 74, and a buried region 128 (an example of the “p-type region” according to the present disclosure) provided in the GaN substrate 10. The base region 123, the guard ring structure 74, and the buried region 128 are each the p-type region. The base region 123, the guard ring structure 74, and the buried region 128 each include Mg as p-type impurities. The base region 123, the guard ring structure 74, and the buried region 128 are formed such that the impurity ions of Mg are implanted to the GaN substrate 10 and are then subjected to annealing. The buried region 128 is the region of p⁺-type. The base region 123 and the guard ring structure 74 are each of p-type or p⁻-type. The base region 123 is provided on the buried region 128.

The guard ring structure 74 is configured such that a thin p-type layer surrounds the circumference of the active area into a ring-like shape. While FIG. 17 illustrates the case of including the plural (two, for example) guard ring structures 74 provided separately from each other, the present embodiment may include the single guard ring structure 74. In addition, the guard ring structure 74 may be implemented by the base region 123 or the buried region 128, or may have any other structures. For example, the guard ring structure 74 may be implemented by a region having a concentration or implanted-peak depth of impurity ions different from the base region 123 and the buried region 128.

The GaN semiconductor device 100 including the guard ring structure 74 facilitates a spread of a depletion layer in a gate-off state toward the edge side on the outer circumference of the GaN substrate 10. The GaN semiconductor device 100 with this configuration thus can improve the breakdown voltage of the vertical MOSFET 1 more than the case without including the guard ring structure 74.

The edge termination area 130 illustrated in FIG. 18 includes the JTE structure 78. The JTE structure 78 may include either a single impurity region or two or more of impurity regions having different concentrations. Either cases can have a preferable configuration determined as appropriate.

For example, the JTE structure 78 includes a first doped region 35 and a second doped region 36. The second doped region 36 has a lower concentration of p-type impurities than the first doped region 35. Setting the p-type impurity concentration of the second doped region 36 to be lower than that of the first doped region 35 facilitates the spread of the depletion layer in the gate-off state toward the end part on the outer circumference side of the GaN substrate 10. The GaN semiconductor device 100 with this configuration thus can improve the breakdown voltage of the vertical MOSFET 1 more than the case without including the guard ring structure 78.

The edge termination area 130 may include both the guard ring structure 74 illustrated in FIG. 17 and the JTE structure 78 illustrated in FIG. 18. The configuration of the GaN semiconductor device 100 having both the guard ring structure 74 and the JTE structure 78 can also improve the breakdown voltage of the vertical MOSFET 1.

The configuration according to the present disclosure may be applied to the buried region 128 of the edge termination area 130 illustrated in FIG. 17 and FIG. 18. For example, the concentration of Mg in the buried region 128 (the entire Mg concentration) is in a range of 5×10¹⁸ cm⁻³ or higher and 1×10²¹ cm⁻³ or smaller. The buried region 128 includes the Mg segregation part P1 in which Mg is partly segregated (refer to FIG. 10) and the matrix P2 in which no Mg is segregated (refer to FIG. 10). The concentration of Mg in the Mg segregation part P1 (the segregation Mg concentration) is 4.6 times or smaller as high as that in the matrix P2 (the matrix Mg concentration).

The buried region 128 having the characteristics regarding the concentration as described above can be formed by the same method as that for the contact region 25 described above with reference to FIG. 4C to FIG. 4F. Since the buried region 128 is located at a deep position under the front surface 10a of the GaN substrate 10, the energy upon the implantation of each of Mg and N when the buried region 128 is formed may be set to be larger than that when the contact region 25 is formed. The energy upon the implantation of Mg and N may be determined as appropriate depending on the depth from the front surface 10a of the GaN substrate 10. This embodiment with such a configuration can also provide the contact region 25 with the higher effective Na and the greater electrical characteristics, such as a smaller variation in resistance.

### OTHER EMBODIMENTS

While the present disclosure has been described above by reference to Embodiments 1 to 4, it should be understood that the present disclosure is not intended to limit the descriptions and the drawings composing part of this disclosure. Various alternative embodiments and modified examples will be apparent to those skilled in the art according to this disclosure.

For example, the gate insulating film 42 is not limited to the SiO₂ film but may be any other insulating films. Examples used as the gate insulating film 42 include a silicon oxynitride (SiON) film, a strontium oxide (SrO) film, a silicon nitride (Si₃N₄) film, and an aluminum oxide (Al₂O₃) film. The gate insulating film 42 may also be implemented by a composite film including some of the respective insulating films as described above. The vertical MOSFET including an insulating film other than the SiO₂ film used as the gate insulating film 42 can also be referred to as a vertical MISFET. Such a MISFET encompasses more inclusive insulated gate transistors including a MOSFET.

Further, the respective embodiments are illustrated above with the case in which the contact region 25 is included in the vertical MISFET, but the present disclosure is not limited to this case. The contact region 25 may be included not in the lateral MISFET in which a current flows in a direction perpendicular to the GaN substrate but in a lateral MISFET in which a current flows in a horizontal direction of the GaN substrate.

Further, the respective embodiments are illustrated above with the case in which the electrode in contact with the contact region 25 is the source electrode 54, but the present disclosure is not limited to this case. The contact region 25 may be in contact with any other electrode, instead of the source electrode. In addition, the p-type region, which is illustrated above with the contact region 25, may be included in any other element, such as a bipolar transistor, a diode, a capacitive element, or a resistive element, instead of the MOSFET.

Further, the manufacturing method according to one embodiment of the present disclosure may execute the ion implantation in the respective steps illustrated with reference to FIG. 4A to FIG. 4D in a state in which the front surface 10a of the GaN substrate 10 is covered with an insulating film (a through-film). Examples of such a through-film include a SiO₂ film, a SiN film, and an AlN film.

It should be understood that the present disclosure can include various embodiments not disclosed herein, and can include at least any of omissions, replacements, or modifications of the constitutional elements without departing from the teaching of the respective embodiments and modified examples described above. It should also be understood that the effects described herein are illustrated merely as some examples that are not limited to the above descriptions, and the present disclosure may have other effects not disclosed herein.

The present disclosure can also have the following configurations.

(1) A nitride semiconductor device comprising:
a nitride semiconductor; and
a p-type region provided in the nitride semiconductor,
wherein:
the p-type region includes an acceptor element and entirely has a concentration in a range of 5×10¹⁸ cm³ or higher and 1×10²¹ cm³ or lower;
the p-type region includes
   a segregation part in which the acceptor element is partly segregated, and
   a matrix in which the acceptor element is not segregated; and
the concentration of the acceptor element in the segregation part is 4.6 times or smaller as high as that in the matrix.

(2) The nitride semiconductor device of the above (1), wherein the concentration of the acceptor element in the segregation part is 0.4 times or greater as high as that in the matrix.

(3) The nitride semiconductor device of the above (1) or (2), wherein a product of a sheet resistance in the p-type region by the concentration of the acceptor element in the matrix is 1.6×10²⁴ Ω/(sq·cm³) or smaller.

(4) The nitride semiconductor device of any one of the above (1) to (3), wherein a sheet resistance in the p-type region is 1.8×10′ Ω/sq or smaller.

(5) The nitride semiconductor device of any one of the above (1) to (4), wherein the concentration of the acceptor element in the matrix is 5×10¹⁸ cm⁻³ or higher and 2×10²⁰ cm⁻³ or lower.

(6) The nitride semiconductor device of any one of the above (1) to (5), further comprising an electrode in contact with the p-type region,
wherein a contact resistance between the p-type region and the electrode is 0.2 Ωcm² or smaller.

(7) The nitride semiconductor device of any one of the above (1) to (6), further comprising a p-type well region provided in the nitride semiconductor and having a lower concentration of the acceptor element than the p-type region.

(8) The nitride semiconductor device of any one of the above (1) to (5), further comprising:
a p-type well region provided in the nitride semiconductor and having a lower concentration of the acceptor element than the p-type region;
an n-type source region provided on a front surface side of the p-type well region;
a gate insulating film provided on the p-type region;
a gate electrode provided on the gate insulating film;
a source electrode provided to be in contact with the p-type region and the n-type source region; and
a drain electrode provided on a side of the nitride semiconductor opposite to a side on which the source electrode is deposited.

(9) The nitride semiconductor device of any one of the above (1) to (8), wherein a thickness of the p-type region is smaller than 80 nanometers.

(10) The nitride semiconductor device of any one of the above (1) to (9), wherein the nitride semiconductor includes a low-dislocation free-standing gallium nitride (GaN) substrate having a threading dislocation density of less than 1×10⁷ cm⁻².

(11) The nitride semiconductor device of any one of the above (1) to (10), wherein the acceptor element includes at least either magnesium (Mg) or beryllium (Be).

(12) A method of manufacturing a nitride semiconductor device, comprising:
implanting impurity ions of an acceptor element from a front surface side of a nitride semiconductor into a predetermined region of the nitride semiconductor;
implanting impurity ions of nitride from the front surface side into the predetermined region before or after the implanting the acceptor element; and
forming a p-type region in the predetermined region of the nitride semiconductor by subjecting, to annealing, the nitride semiconductor to which the acceptor element and the nitride are implanted,
wherein:
the p-type region includes a segregation part in which the acceptor element is partly segregated, and a matrix in which the acceptor element is not segregated;
the implanting the acceptor element is executed such that the entire predetermined region has a concentration of the acceptor element in a range of 5×10¹⁸ cm⁻³ or higher and 1×10²¹ cm⁻³ or lower; and
the forming the p-type region sets a condition for the annealing so that the concentration of the acceptor element in the segregation part is 4.6 times or smaller as high as that in the matrix.

(13) The method of manufacturing the nitride semiconductor device of the above (12), wherein the forming the p-type region sets a maximum temperature for the annealing in a range of 1300° C. or higher and 2000° C. or lower.

What is claimed is:

1. A nitride semiconductor device comprising:
a nitride semiconductor; and
a p-type region provided in the nitride semiconductor,
wherein:
the p-type region includes an acceptor element and entirely has a concentration in a range of 5×10¹⁸ cm⁻³ or higher and 1×10²¹ cm⁻³ or lower;
the p-type region includes
a segregation part in which the acceptor element is partly segregated, and
a matrix in which the acceptor element is not segregated; and
the concentration of the acceptor element in the segregation part is 4.6 times or smaller as high as that in the matrix.

2. The nitride semiconductor device of claim 1, wherein the concentration of the acceptor element in the segregation part is 0.4 times or greater as high as that in the matrix.

3. The nitride semiconductor device of claim 1, wherein a product of a sheet resistance in the p-type region by the concentration of the acceptor element in the matrix is 1.6×10²⁴ Ω/(sq·cm³) or smaller.

4. The nitride semiconductor device of claim 1, wherein a sheet resistance in the p-type region is 1.8×10⁵ Ω/sq or smaller.

5. The nitride semiconductor device of claim 1, wherein the concentration of the acceptor element in the matrix is 5×10¹⁸ cm⁻³ or higher and 2×10²¹ cm⁻³ or lower.

6. The nitride semiconductor device of claim 1, further comprising an electrode in contact with the p-type region,
wherein a contact resistance between the p-type region and the electrode is 0.2 Ωcm² or smaller.

7. The nitride semiconductor device of claim 1, further comprising a p-type well region provided in the nitride semiconductor and having a lower concentration of the acceptor element than the p-type region.

8. The nitride semiconductor device of claim 1, further comprising:
a p-type well region provided in the nitride semiconductor and having a lower concentration of the acceptor element than the p-type region;
an n-type source region provided on a front surface side of the p-type well region;
a gate insulating film provided on the p-type region;
a gate electrode provided on the gate insulating film;
a source electrode provided to be in contact with the p-type region and the n-type source region; and
a drain electrode provided on a side of the nitride semiconductor opposite to a side on which the source electrode is deposited.

9. The nitride semiconductor device of claim 1, wherein a thickness of the p-type region is smaller than 80 nanometers.

10. The nitride semiconductor device of claim 1, wherein the nitride semiconductor includes a low-dislocation free-standing gallium nitride (GaN) substrate having a threading dislocation density of less than 1×10⁷ cm⁻².

11. The nitride semiconductor device of claim 1, wherein the acceptor element includes at least either magnesium (Mg) or beryllium (Be).

12. A method of manufacturing a nitride semiconductor device, comprising:
implanting impurity ions of an acceptor element from a front surface of a nitride semiconductor into a predetermined region of the nitride semiconductor;
implanting impurity ions of nitride from the front surface into the predetermined region before or after the implanting the acceptor element; and
forming a p-type region in the predetermined region of the nitride semiconductor by subjecting, to annealing, the nitride semiconductor to which the acceptor element and the nitride are implanted,
wherein:
the p-type region includes a segregation part in which the acceptor element is partly segregated, and a matrix in which the acceptor element is not segregated;
the implanting the acceptor element is executed such that the entire predetermined region has a concentration of the acceptor element in a range of 5×10¹⁸ cm⁻³ or higher and 1×10²¹ cm⁻³ or lower; and
the forming the p-type region sets a condition for the annealing so that the concentration of the acceptor element in the segregation part is 4.6 times or smaller as high as that in the matrix.

13. The method of manufacturing the nitride semiconductor device of claim 12, wherein the forming the p-type region sets a maximum temperature for the annealing in a range of 1300° C. or higher and 2000° C. or lower.
